(19) United States
(12) Patent Application Publication
(10) Pub. No.: US 2007/0015338 A1
(43) Pub. Date: Jan. 18, 2007

(54) Substrate applicable to both wire bonding and flip chip bonding, smart card modules having the substrate and methods for fabricating the same

(75) Inventors: Seok-Won Lee, Seongnam-si (JP); Kyoung-Sei Choi, Cheonan-si (KR); Dong-Han Kim, Osan-si (KR); Young-Hoon Ro, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/487,484

(22) Filed: Jul. 17, 2006

(30) Foreign Application Priority Data
Jul. 18, 2005 (KR) 10-2005-0064770

(51) Int. Cl. H01L 21/76

(52) U.S. Cl. 438/400

(57) ABSTRACT

A substrate, a smart card module having the substrate and methods for fabricating the same are provided. A substrate having metal patterns formed on both sides and applicable to both wire bonding and flip chip bonding, a smart card module having the same and methods of fabricating the same are also provided. The substrate may include an insulating layer, an upper metal pattern, a bottom metal pattern, a first plating layer, a second plating layer and a substrate. The insulating layer may have a plurality of via holes. The upper metal pattern may be formed on the insulating layer and side surfaces of the plurality of via holes. The bottom metal pattern may be formed on the bottom of the insulating layer and electrically connected to the upper metal pattern. The first plating layer may be formed on the upper metal pattern and the upper surface of the bottom metal pattern. The second plating layer may be formed on the bottom of the bottom metal pattern. The substrate may include contact holes having side surfaces of the plurality of via holes covered by the upper metal pattern and the first plating layer. The bottom surface of the insulating layer may be supported by the bottom metal pattern and the first plating layer.

### PRIORITY STATEMENT

This application claims priority under 35 U.S.C. § 119 to Korean Patent Application No. 10-2005-0064770, filed on Jul. 18, 2005, in the Korean Intellectual Property Office (KIPO), the entire contents of which are incorporated herein by reference.

### BACKGROUND

1. Field

Example embodiments of the present invention relate to a substrate, a smart card module having the substrate and methods for fabricating the same. Other example embodiments of the present invention relate to a substrate having metal patterns formed on both sides and applicable to both wire bonding and flip chip bonding, a smart card module having the same and methods of fabricating the same.

2. Description of the Related Art

The term “smart card” may be used in various industrial fields. In the international standardization organization (ISO), a smart card may be defined as a card including at least one of integrated circuits. In order to process given transactions, the smart card generally denotes a plastic card including an integrated circuit chip with a microprocessor, an operating system, a security module and memory. A smart card may be used in diverse application fields (e.g., traffic, distribution, Internet, finance, government, authentication, reservation, prescription and/or identification).

The smart card may be manufactured by connecting a semiconductor chip to a substrate having a metal pattern. The semiconductor chip may be sealed with the substrate using a sealing resin. If the metal pattern of the substrate is a single metal layer, wire bonding may be used to connect the semiconductor chip to the substrate of the smart card module. If the substrate includes metal patterns formed on both sides of the substrate, the semiconductor chip may be connected to the substrate through flip chip bonding.

The substrates may have different structures for wire bonding as opposed to flip chip bonding. In the conventional art, a micro via may be formed on the substrate using a laser. Manufacturing the smart card module according to the conventional methods may be costly. Also, it may be difficult to perform wire bonding on a region of the substrate where a via hole is activated.

### SUMMARY

Example embodiments of the present invention relate to a substrate, a smart card module having the substrate and methods for fabricating the same. Other example embodiments of the present invention relate to a substrate having metal patterns formed on both sides and applicable to both wire bonding and flip chip bonding, a smart card module having the same and methods of fabricating the same.

Example embodiments of the present invention provide a substrate that may include metal patterns formed on both sides, without forming a micro via, applicable to both wire bonding and/or flip chip bonding.

According to example embodiments of the present invention, there is provided a substrate that may include an insulating layer having a plurality of via holes around a center portion of the insulating layer; an upper metal pattern on an upper surface of the insulating layer and on a side surface of the plurality of via holes; a bottom metal pattern on the bottom surface of the insulating layer to support the insulating layer and the upper metal pattern, and electrically connected to the upper metal pattern; a first plating layer covering the upper surface of the upper metal pattern and exposed portions of the upper surface of the bottom metal pattern; a second plating layer on a bottom surface of the bottom metal pattern; and the substrate having contact holes with side surfaces of the plurality of via holes, which may be covered by the upper metal pattern and the first plating layer, and the bottom surface of the insulating layer, which may be supported by the bottom metal pattern and the first plating layer. The contact holes may have a given size for wire bonding.

According to other example embodiments of the present invention, there is provided a smart card module including a substrate, wherein the substrate may be connected to a semiconductor chip through wire bonding and/or flip chip bonding.

According to still other example embodiments of the present invention, there is provided a method of fabricating a substrate including attaching an upper metal layer and an insulating layer to the substrate, a plurality of via holes penetrating the upper metal layer and the insulating layer from a direction of the upper metal layer, pressing a bottom metal layer on the bottom of the insulating layer, forming an upper metal pattern and a bottom metal pattern by patterning the upper metal layer and the bottom metal layer and forming a first plating layer and a second plating layer on the upper metal pattern and the bottom metal pattern.

A plurality of via holes may penetrate the upper metal layer and the insulating layer, connecting the upper metal layer to side surfaces of the plurality of via holes, and transforming the upper metal layer at a lower portion of the plurality of via holes. The transformation of the upper metal layer may be in the form of a burr. The burr may be formed on the upper metal layer under side surfaces of the plurality of via holes. The burr may be formed at the lower portion of the plurality of via holes using a pressing process, a drilling process and/or a punching process.

According to example embodiments of the present invention, the electrical connection between the upper metal layer and the bottom metal layer may be formed using a pressing process, a drilling process and/or a punching process without forming a micro via using the laser and so the manufacturing cost of the substrate may be reduced. A smart card module having the substrate in accordance with example embodiments of the present invention may be manufactured by wire bonding and/or flip chip bonding.

### BRIEF DESCRIPTION OF THE DRAWINGS

Example embodiments of the present invention will be more clearly understood from the following detailed description taken in conjunction with the accompanying drawings. FIGS. 1-13 represent non-limiting, example embodiments of the present invention as described herein.

FIG. 1-3 are diagrams illustrating a smart card module having a substrate according to example embodiments of the present invention;

FIG. 4 is a flowchart illustrating a method of manufacturing a substrate according to example embodiments of the present invention; and

FIGS. 5-13 are diagrams illustrating a method of manufacturing a substrate according to example embodiments of the present invention.

### DETAILED DESCRIPTION OF THE EXAMPLE EMBODIMENTS

Various example embodiments of the present invention will now be described more fully with reference to the accompanying drawings, in which example embodiments of the present invention are shown. Example embodiments of the present invention should not be construed as being limited to the example embodiments set forth herein; rather, these example embodiments are provided so that this disclosure will be thorough and complete, and will fully convey the concept of the invention to those skilled in the art. Like numbers refer to like elements throughout the description of the figures.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention relate to a substrate, a smart card module having the substrate and methods for fabricating the same. Other example embodiments of the present invention relate to a substrate having metal patterns formed on both sides and applicable to both wire bonding and flip chip bonding, a smart card module having the same and methods of fabricating the same.

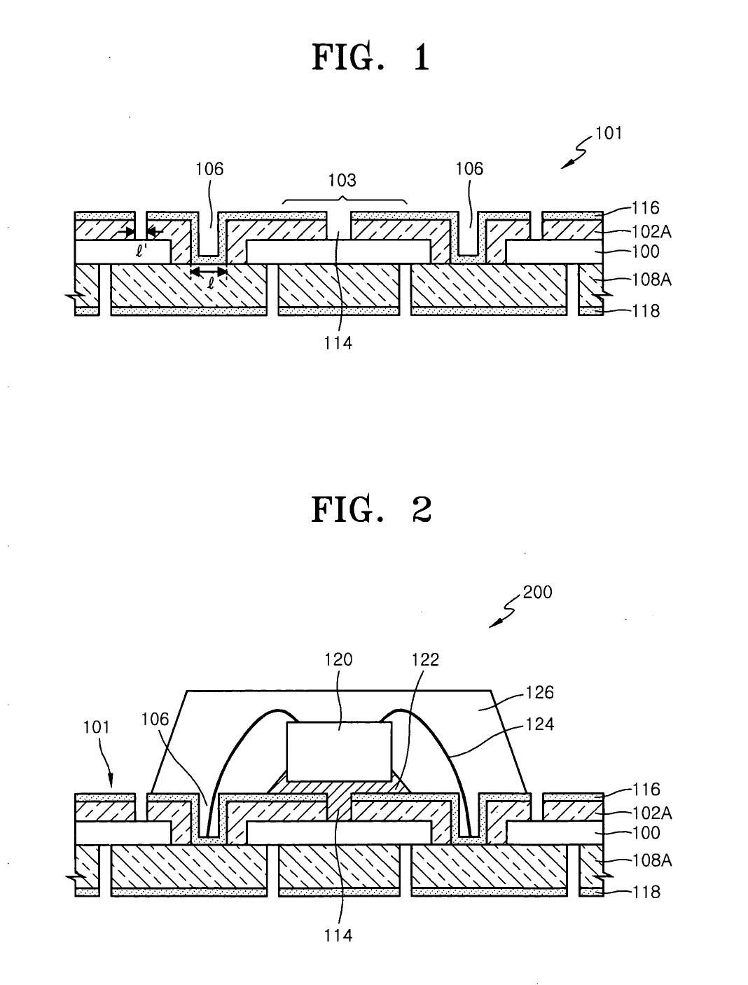

FIG. 1 is a diagram illustrating a substrate according to example embodiments of the present invention.

Referring to FIG. 1, a substrate 101 may include an insulating layer 100 and a plurality of via holes. The plurality of via holes may be formed around a center portion of the substrate. The center portion may be a region wherein a die pad 103 may be formed and a semiconductor chip may be embedded. An upper metal pattern 102A may be bonded on an upper surface and side surfaces of the insulating layer 100.

The insulating layer 100 may be from one insulating material selected from the group including glass fabric, epoxy, BT resin, polymer film and insulating adhesive. The upper metal pattern 102A may be formed of copper or a similar material. The upper metal pattern 102A may be laminated where the upper metal pattern 102A contacts an insulating layer 100. The upper metal pattern 102A may have a foil shape. Copper may be formed on the insulating layer 100 through electroplating. A die contact hole 114 may be formed on the die pad 103 to increase adhesion between the semiconductor chip and the insulating layer 100. A die adhesive may be soaked in, or applied to, the die contact hole 114 to more firmly fix the semiconductor chip on the die pad 103.

The substrate 101 may also include a bottom metal pattern 108A that is attached to a bottom surface of the insulating layer 100. The bottom metal pattern 108A may support the bottom of the insulating layer 100 and the upper metal pattern 102A formed around the center portion. The upper metal pattern 102A, formed on the sidewalls of the plurality of via holes, may be transformed. A transformation 104 of the upper metal pattern 102A (e.g., a burr 104) may be created at the sidewalls of the plurality of via holes as illustrated in FIG. 7. A length l of the upper metal pattern 102A formed under the sidewalls of the plurality of via holes must be the same or longer than a length l′ of a bottom surface of a plurality of via holes formed on the insulating layer 100. The bottom metal pattern 108A may be electrically connected to the upper metal pattern 102A via the burr. Because the burr is pressed while compressing the bottom metal pattern 108A onto the insulating layer, the burr may become smaller. The burr may not be identified by the human eye after compressing.

The substrate 101 may further include a first plating layer 116 covering the upper surface of the upper metal pattern 102A and exposed portions of an upper surface of the bottom metal pattern 108A. A second plating layer 118 may cover a bottom surface of the bottom metal pattern 108A. The first plating layer 116 and the second plating layer 118 may be formed of a single layer selected from the group including gold (Au), nickel (Ni) and palladium (Pd), or a multiple layer including one selected from the group including gold (Au), nickel (Ni) and palladium (Pd).

Contact holes 106 may be formed on the substrate 101 while forming the first plating layer 116. The sidewalls of the contact holes 106 may be covered by the upper metal pattern 102A and the first plating layer 116. The bottom surface of the contact holes 106 may be covered by the bottom metal pattern 108A and the first plating layer 116. The contact holes 106 may penetrate through the die pad 103 and may have a given size for performing wire bonding. The contact holes 106 may have a structure to electrically connect the upper metal pattern 102A and the bottom metal pattern 108A.

The substrate 101 may have metal patterns on both sides without forming a micro via, and applicable to both wire bonding and/or flip chip bonding. The die pad hole 114 may be formed on the die pad region 103 to enhance the adhesive force of a semiconductor chip.

FIG. 2 is a diagram illustrating a smart card module including a substrate according to example embodiments of the present invention.

Referring to FIG. 2, a smart-card module 200 may include the substrate 101 illustrated in FIG. 1. The smart card module 200 may further include a semiconductor chip 120 embedded on the substrate 101 through wire bonding 124. In order for the semiconductor chip 120 and the upper metal pattern 102A to demonstrate insulation properties, a die adhesive 122 may be a non-conductive die adhesive.

A potting end milling method may be used to seal the semiconductor chip 120 and the bonding wire 124 using a seal resin 126. The seal resin 126 may be dispensed and covered on the smart card module layer 101. The seal resin 126 may then be hardened and the upper surface of the hardened seal resin may be grinded. A dam end fill method may also be used to seal the semiconductor chip 120 and the bonding wire 124. A dam may be formed using a seal resin 126 having a higher viscosity, and the inside of the dam may be filled with a material having a lower viscosity. The dam may then be hardened by irradiating the UV light. The seal resin 126 may be printed via a mask and molded using an epoxy mold compound which may seal the semiconductor chip 120 and the bonding wire 124.

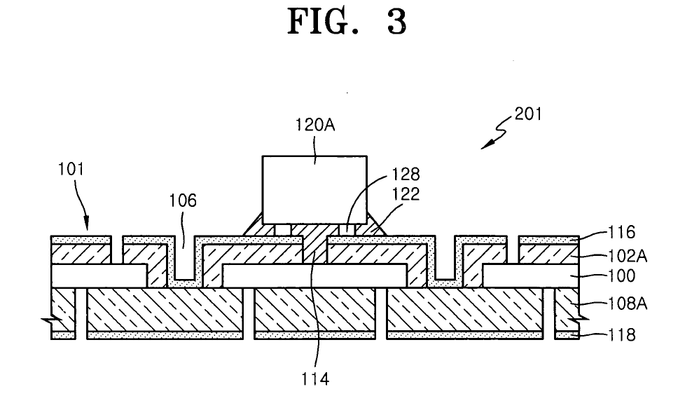

FIG. 3 is a diagram illustrating a smart card module including a substrate according to other example embodiments of the present invention.

Referring to FIG. 3, the smart card module 201 may be electrically connected to the substrate illustrated in FIG. 1 using flip chip bonding through a bump 128 of a semiconductor chip 120A. The bump 128 may be additionally formed on the semiconductor chip 120A. In order to connect the semiconductor chip 120A and the substrate 101, a non-conductive die adhesive 122 may be previously coated on a die pad region of the substrate 101. Heat and pressure is simultaneously applied to harden the die adhesive 122 which may connect the bump 128 to the upper metal pattern 102A of the first plating layer 116.

In order to connect the semiconductor chip 120A and a substrate 101 according to other example embodiments of the present invention, a first plating layer 116 may be formed on the upper metal pattern 102A, where the bump 128 is connected, in order to perform soldering. The upper metal pattern 102A and the semiconductor chip 120 may be connected through the soldering. The die adhesive 122 may be dispensed to fill a space between the semiconductor chip 120 and the substrate 101. The smart card module 201 may be sealed using the seal resin 126 covering the semiconductor chip 120A.

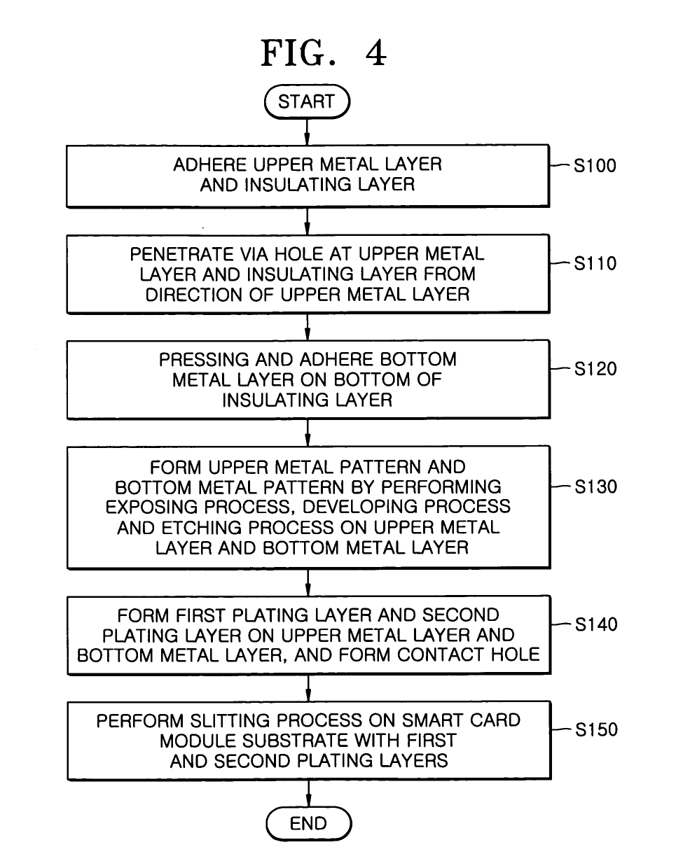

FIG. 4 is a flowchart of a method of fabricating a substrate according to example embodiments of the present invention.

Referring to FIG. 4, an insulating layer may adhere to a copper upper metal layer in S100. A plurality of via holes may penetrate the upper metal layer and the insulating layer in a direction to the upper metal layer in S110 in order to create a burr on the upper metal layer. A bottom metal layer may be compressed to the bottom of the insulating layer in S120. While compressing, the burr may make a relatively firm electrical connection between the upper metal layer and the bottom metal layer in the region of the plurality of via holes. After compressing, an exposing process, a developing process and/or an etching process may be performed on the upper metal layer and the bottom metal layer to form an upper metal pattern and a bottom metal pattern in S130. A first plating layer may be formed on the upper metal pattern, and the second plating layer may be formed on the bottom metal pattern in S140. Contact holes may then be formed on the substrate.

The electrical connection between the upper metal pattern and the bottom metal pattern may become unstable even though the burr formed on the upper metal pattern connects the upper metal pattern and the bottom metal pattern. The first metal layer may connect the upper metal pattern and the bottom metal pattern, in order to retard, or prevent, instability of the electrical connection between the upper metal pattern and the bottom metal pattern. A slitting process may be performed to cut the smart card module having the first and the second plating layers to a given size in S150.

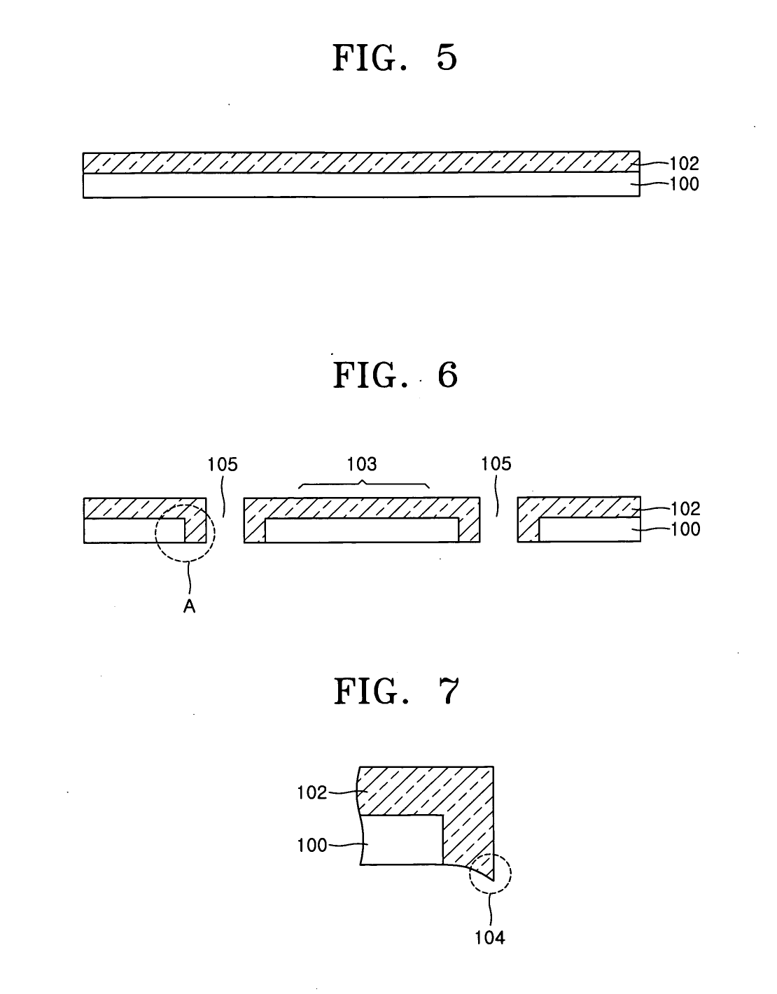

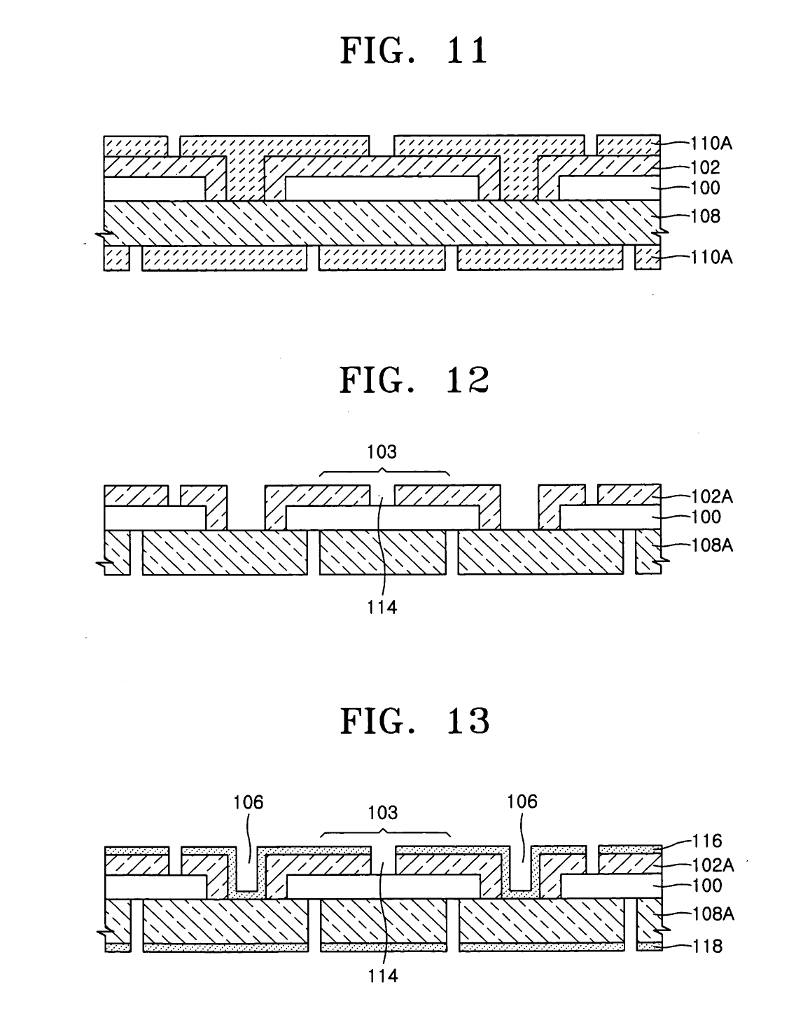

FIGS. 5-13 are diagrams illustrating a method of manufacturing a substrate according to example embodiments of the present invention.

Referring to FIG. 5, the insulating layer 100 may be adhered to the upper metal layer 102. An insulating substrate may be used as the insulating layer instead of using an adhesive insulating layer. The insulating substrate may be made of one selected from the group including glass fabric, epoxy, BT resin, and polymer film. The insulating layer 100 and the upper metal layer 102 may be bonded using a lamination method.

Referring to FIG. 6, there may be a plurality of via holes 105 in given locations around a die pad region 103. A reel to reel feeding may be performed by winding the bonded upper metal layer 102 and insulating layer 100 onto a reel. The plurality of via holes 105 may be formed where a wire bonding may be performed. In order to penetrate the plurality of via holes 105, one of a pressing process, a drilling process and/or a punching process may be used. When the plurality of via holes 105 are penetrated, a burr may be created at a lower portion of the plurality of via holes 105 in region ‘A’. The burr may be a transformation of the upper metal layer 102.

FIG. 7 illustrates the burr 104 as the transformation of the upper metal layer 102. The burr may occur as a result of inferiority in the pressing, the drilling and/or the punching presses. But, the burr may be a means to accomplish the electrical connection between the upper metal layer 102 and the bottom metal layer 108 in example embodiments of the present invention. The burr 104 of the upper metal layer 102, which is formed lower than the insulating layer 100, may physically contact the bottom metal layer by a succeeding process to complete the electrical connection between the upper metal pattern 102 and the bottom metal layer 108.

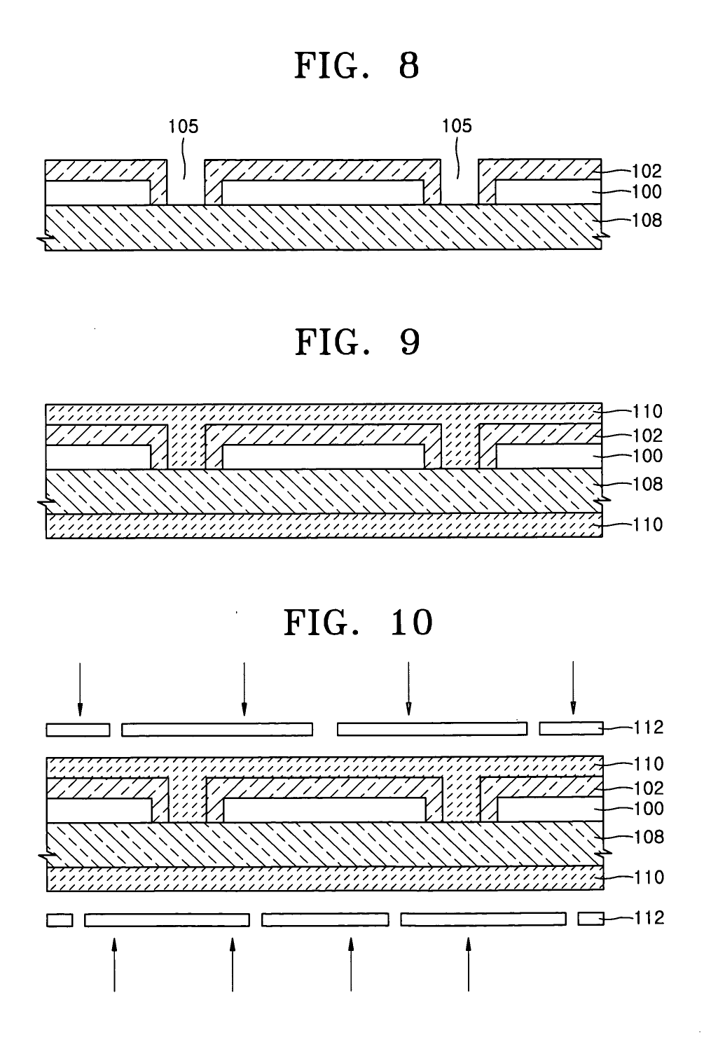

Referring to FIG. 8, the bottom metal layer 108 may be bonded on the bottom of the burr 104 using adhesive (not shown). If the insulating layer 100 acts as an adhesive, a bottom metal layer 108 may be about the same or thicker than an upper metal layer 102 for mechanical stabilization. Copper material may be used to form the bottom metal layer 108 having a thickness of about 100 μm. In order to further complete the electrical connection of the burr 104, the upper metal layer 102 and the bottom metal layer 108 may be compressed via a lamination method, and the adhesive may be hardened. While compressing the bottom metal layer 108, the burr may be pressed. The burr 104 may become smaller than may be identified by the human eye.

Referring to FIGS. 9-12, a dry film, having photo-resist characteristics, may be laminated on the upper metal layer 102 and the bottom metal layer 108. The exposing process and/or the developing process may be performed using a mask 112 to convert the dry film 110 to a dry film pattern 110A. The upper metal pattern 102A may be formed by etching the upper metal layer 102, and the bottom metal pattern 108A may be formed by etching the bottom metal layer 108 using the dry film pattern 110A as an etching mask. The upper metal pattern 102A and the bottom metal pattern 108A may become isolated. A die contact hole 114 may be additionally formed on the die pad region of the upper metal pattern 102A to enhance adhesion between the semiconductor chip and the insulating layer 100. The dry film pattern 110A may then be removed and the cleaning process may be performed.

Referring to FIG. 13, the first plating layer 116 and the second plating layer 118 may be formed on the upper metal pattern 102A and the bottom metal pattern 108A. The first plating layer 116 and the second plating layer 118 may be formed of a single layer selected from the group including gold (Au), nickel (Ni) and palladium (Pd) or a multiple layer including one selected from the group including gold (Au), nickel (Ni) and palladium (Pd). The first plating layer 116 may be coated on the sidewalls of the plurality of via holes and the bottom metal pattern. The upper metal layer 102 and the bottom metal layer 108 may be electrically connected by the burr 104 in FIG. 7. If the electrical connection between the upper metal layer 102 and the bottom metal layer 108 becomes unstable, the first plating layer 116 may additionally connect the upper metal pattern 102A and the bottom metal pattern 108A. The electrical connection between the upper metal pattern 102A and the bottom metal pattern 108A may then become complete without the added cost of forming micro via using a laser. The slitting process may be performed on the smart card module substrate with the first and the second plating layers 116 and 118 to cut it into a desired size.

According to example embodiments of the present invention, the method of forming a substrate may form the electrical connection between the upper metal layer and the bottom metal layer without the added cost of forming micro via using the laser. According to the method of forming a substrate, the electrical connection may be accomplished using a pressing process, a drilling process and/or a punching process, and so, the manufacturing cost of the substrate may be reduced.

According to example embodiments of the present invention, the method of forming a substrate may provide a substrate applicable to both wire bonding and/or flip chip bonding. Wire bonding and/or flip chip bonding may be selected to manufacture the smart card module using the substrate according to example embodiments of the present invention. The time of replacing products may be reduced, productivity of the smart card module may be improved, and it may be possible to mass-produce the smart card modules using the substrate formed according to example embodiments of the present invention.

The foregoing is illustrative of example embodiments of the present invention and is not to be construed as limiting thereof. While example embodiments of the present invention have been particularly shown and described with reference to the example embodiments shown in the drawings, it will be understood by those of ordinary skill in the art that various changes in form and details may be made therein without departing from the spirit and scope of example embodiments of the present invention as defined by the following claims.

What is claimed is:

1. A substrate comprising:
an insulating layer having a plurality of via holes around a center portion of the insulating layer;
an upper metal pattern on an upper surface of the insulating layer and on side surfaces of the plurality of via holes;
a bottom metal pattern on a bottom surface of the insulating layer to support the insulating layer and the upper metal pattern, and electrically connected to the upper metal pattern;
a first plating layer covering the upper surface of the upper metal pattern and exposed parts of the upper surface of the bottom metal pattern;
a second plating layer on a bottom surface of the bottom metal pattern; and
the substrate having contact holes with side surfaces of the plurality of via holes, which is covered by the upper metal pattern and the first plating layer, and the bottom surface of the insulating layer, which is supported by the bottom metal pattern and the first plating layer.

2. The substrate of claim 1, wherein the upper metal pattern on the center portion of the insulating layer has a die bonding hole to absorb a die adhesive.

3. The substrate of claim 1, wherein the insulating layer is made of one selected from the group including glass fabric, epoxy, BT resin, polymer film and insulating adhesive.

4. The substrate of claim 1, wherein the contact holes of the substrate have a given size for wire bonding.

5. The substrate of claim 1, wherein the first plating layer and the second plating layer are a single layer selected from the group including gold (Au), nickel (Ni) and palladium (Pd), or a multiple layer including one selected from the group including gold (Au), nickel (Ni) and palladium (Pd).

6. A smart card module comprising:
the substrate of claim 1;
a semiconductor chip bonded on a die pad formed on a center portion of the substrate using a die adhesive;
a wire connecting the semiconductor chip and a second plating layer in a contact hole of the substrate; and
a seal material for sealing the semiconductor chip and the wire.

7. The smart card module of claim 6, wherein the smart card module further includes:
a semiconductor chip electrically connected to an upper metal pattern on a die pad in a center portion of the substrate through a bump.

8. The smart card module of claim 7, wherein the smart card module further includes a seal resin for sealing the smart card module and the semiconductor chip.

9. The smart card module of claim 7, wherein the smart card module further includes an adhesive applied between the semiconductor chip and the substrate.

10. A method of fabricating a substrate, the method comprising:
attaching an upper metal layer and an insulating layer;
a plurality of via holes penetrating the upper metal layer and the insulating layer from a direction of the upper metal layer;
pressing a bottom metal layer on a bottom of the insulating layer;
forming an upper metal pattern and a bottom metal pattern by patterning the upper metal layer and the bottom metal layer; and
forming a first plating layer and a second plating layer on the upper metal pattern and the bottom metal pattern.

11. The method of claim 10, wherein during attaching of the upper metal layer, an adhesive used as the insulating layer is coated on the upper metal layer.

12. The method of claim 11, wherein the thickness of the bottom metal layer is the same or thicker than that of the upper metal layer when the insulating layer is used as the adhesive.

13. The method of claim 10, wherein during attaching of the upper metal layer, the upper metal layer and the insulating layer are laminated.

14. The method of claim 13, wherein the insulating layer is made of one selected from the group including glass fabric, epoxy, BT resin and polymer film.

15. The method of claim 10, wherein the plurality of via holes penetrate through the upper metal layer and the insulating layer to connect the upper metal layer to side surfaces of the plurality of via holes, and to create a transformation of the upper metal layer at a lower portion of the plurality of via holes.

16. The method of claim 15, wherein the transformation of the upper metal layer is a burr created on the upper metal layer under side surfaces of the plurality of via holes.

17. The method of claim 16, wherein the burr is created at the lower portion of the plurality of via holes using one of a pressing process, a drilling process and a punching process.

18. The method of claim 10, wherein during pressing of the bottom metal layer, the bottom metal layer attaches to the bottom of the insulating layer coating an adhesive on the bottom of the insulating layer, and the bottom metal layer is pressed simultaneously.

19. The method of claim 10, wherein during forming of the upper metal pattern and the bottom metal pattern, a patterning is progressed to form a die bonding hole in a given region of the upper metal layer where a semiconductor chip is embedded.

20. A method of fabricating a smart card module comprising:
forming the substrate fabricated according to claim 10;
bonding a semiconductor chip on a die pad formed on a center portion of the substrate using a die adhesive;
connecting the semiconductor chip and a second plating layer in a contact hole of the substrate through a wire; and
sealing the semiconductor chip and the wire with a seal material.
